(19) United States
(12) Patent Application Publication
(10) Pub. No.: US 2023/0009466 A1
(43) Pub. Date: Jan. 12, 2023

(54) MODULAR PAYLOAD FOR UNMANNED VEHICLE

(71) Applicant: Booz Allen Hamilton Inc., McLean, VA (US)

(72) Inventors: Annaliese Cunniffe, Alexandria, VA (US); Robert Nicholas, Alexandria, VA (US)

(73) Assignee: Booz Allen Hamilton Inc., McLean, VA (US)

(21) Appl. No.: 17/371,215

(22) Filed: Jul. 9, 2021

(51) Int. Cl. G06F 30/10; G06F 30/23

(52) U.S. Cl. CPC G06F 30/10; G06F 30/23

(57) ABSTRACT

Embodiments disclose a method for determining a payload platform configuration. The method involves receiving platform specifications, receiving payload specifications for a first payload and a second payload, and receiving operational constraints for a vehicle to which the platform and the second payload will be attached, the operational constraints being based on payload specifications for the first payload. The method involves using finite element analysis and/or dynamic load analysis to generate predictions about operational performance of the vehicle and corresponding properties of the platform, the predictions being based on payload specifications for the second payload. The method involves generating at least one of: a platform configuration that meets a predetermined operational performance of the vehicle, the platform configuration being based on payload specifications for the second payload; or an operational performance result for a predetermined platform configuration, the operational performance result being based on payload specifications for the second payload.

### FIELD

Embodiments relate to a method and system for determining a payload platform configuration for an unmanned vehicle and methods of manufacturing payload platforms.

### BACKGROUND INFORMATION

Unmanned vehicle systems generally have peripherals (e.g., computing devices, sensors, cameras, etc.) that are affixed or removably affixed to a portion of the vehicle to provide functionality to the vehicle. The collection of peripherals is generally referred to as a payload for the vehicle. Known vehicle systems are limited to using native payload support systems that are designed to only operate with OEM components, placement, and configurations. This significantly limits versatility and operability of the vehicle, especially if the situation dictates a tailored or customized payload configuration. With known systems, there is no means to facilitate analysis of size, weight, power, and cost trade-offs for using different (different from what is offered by the OEM) peripherals or payloads. Unmanned vehicles can also carry payloads consisting of items that are transported by the vehicles from one location to another or equipment such as drones or communication equipment, etc.

### SUMMARY

Embodiments can relate to a method for determining a payload platform configuration. The method involves receiving platform specifications, receiving payload specifications for a first payload and a second payload, and receiving operational constraints for a vehicle to which the platform and the second payload will be attached, the operational constraints being based on payload specifications for the first payload. The method involves using finite element analysis (FEA) and/or dynamic load analysis to generate predictions about operational performance of the vehicle and corresponding required properties of the platform, such as the weight-bearing and rigidity of materials, size of platform, shape of platform, and resistance to environmental factors the predictions being based on payload specifications for the second payload. The method involves generating at least one of: a platform configuration that meets a predetermined operational performance of the vehicle, the platform configuration being based on payload specifications for the second payload; or an operational performance result for a predetermined platform configuration, the operational performance result being based on payload specifications for the second payload.

Embodiments can relate to a system for determining a payload platform configuration. The system includes a processor having instructions stored thereon which when executed will cause the processor to execute any of the method steps disclosed herein. The system includes a user interface configured to receive a modification for the platform specifications, the payload specifications, and/or the operational constraints. The processor is configured to dynamically generate the platform configuration that meets a predetermined operational performance of the vehicle and/or the operational performance result for a predetermined platform configuration based on the modification.

Embodiments can relate to a method for determining payload placement on a platform. The method involves receiving platform specifications, receiving payload specifications for a first payload and a second payload, and receiving operational constraints for a vehicle to which the platform and the second payload will be attached, the operational constraints being based on payload specifications for the first payload. The method involves using finite element analysis (FEA) and/or dynamic load analysis to generate predictions about operational performance of the vehicle and properties of the platform, the predictions being based on payload specifications for the second payload. The method involves generating at least one of: a payload placement arrangement for the second payload that meets a predetermined operational performance of the vehicle; or an operational performance result for a predetermined payload placement arrangement for the second payload.

Embodiments can relate to a system for determining payload placement on a platform. The system includes a processor having instructions stored thereon which when executed will cause the processor to execute any of the method steps disclosed herein. The system includes a user interface configured to receive a modification for the platform specifications, the payload specifications, and/or the operational constraints. The processor is configured to dynamically generate the platform placement arrangement that meets a predetermined operational performance of the vehicle and/or the operational performance result for a predetermined platform placement arrangement based on the modification.

Embodiments can relate to a method for manufacturing a payload platform. The method involves receiving platform specifications, receiving payload specifications for a first payload and a second payload, and receiving operational constraints for a vehicle to which the platform and the second payload will be attached, the operational constraints being based on payload specifications for the first payload. The method involves using finite element analysis (FEA) and/or dynamic load analysis to generate predictions about operational performance of the vehicle and corresponding properties of the platform, the predictions being based on payload specifications for the second payload. The method involves generating at least one of: a platform configuration that meets a predetermined operational performance of the vehicle, the platform configuration being based on payload specifications for the second payload; or an operational performance result for a predetermined platform configuration, the operational performance result being based on payload specifications for the second payload. The method involves fabricating the platform.

Embodiments can relate to a method for determining a payload platform configuration. The method involves receiving platform specifications. The method involves receiving operational constraints for a vehicle to which the platform and a payload will be attached. The method involves receiving payload specifications for a payload, the payload being a customized payload for the vehicle. The method involves using finite element analysis (FEA) and/or dynamic load analysis to generate predictions about operational performance of the vehicle and corresponding properties of the platform, the predictions being based on payload specifications for the payload. The method involves generating at least one of: a platform configuration that meets a predetermined operational performance of the vehicle, the platform configuration being based on payload specifications for the payload; or an operational performance result for a predetermined platform configuration, the operational performance result being based on payload specifications for the payload.

Embodiments can relate to a payload platform for an unmanned vehicle including a mounting plate configured to accept at least one modular payload via an aperture arrangement formed within the mounting plate, wherein the aperture arrangement is configured to facilitate repositioning of the at least one modular payload.

### BRIEF DESCRIPTION OF THE DRAWINGS

Other features and advantages of the present disclosure will become more apparent upon reading the following detailed description in conjunction with the accompanying drawings, wherein like elements are designated by like numerals, and wherein:

FIG. 1 shows an exemplary system for determining a payload platform configuration;

FIGS. 2-8 show an exemplary process flow for carrying out an embodiment of a method for determining a payload platform configuration;

FIG. 9 shows an exemplary platform that can be developed by an embodiment of the method, and an exemplary vehicle to which the platform can be attached; and

FIGS. 10-11 show an exemplary platform/payload configuration that can be developed by an embodiment of the method.

FIG. 12 shows an exemplary platform having a slot design.

### DETAILED DESCRIPTION

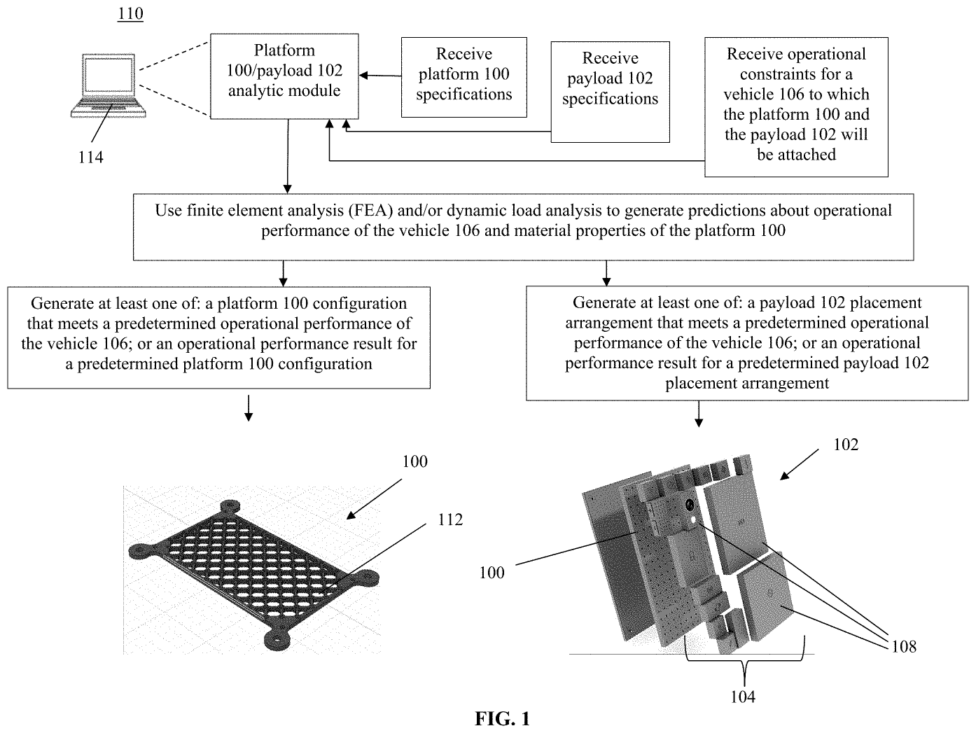

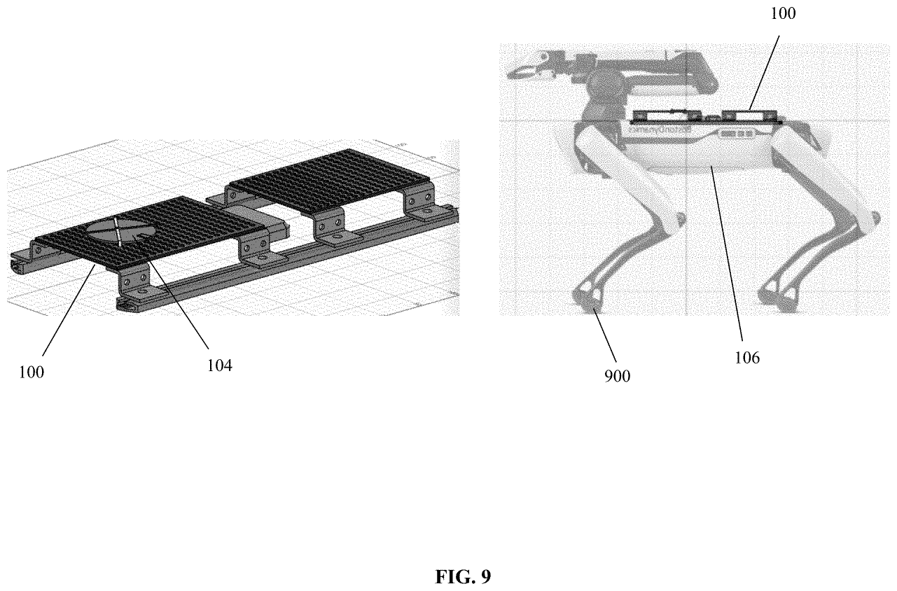

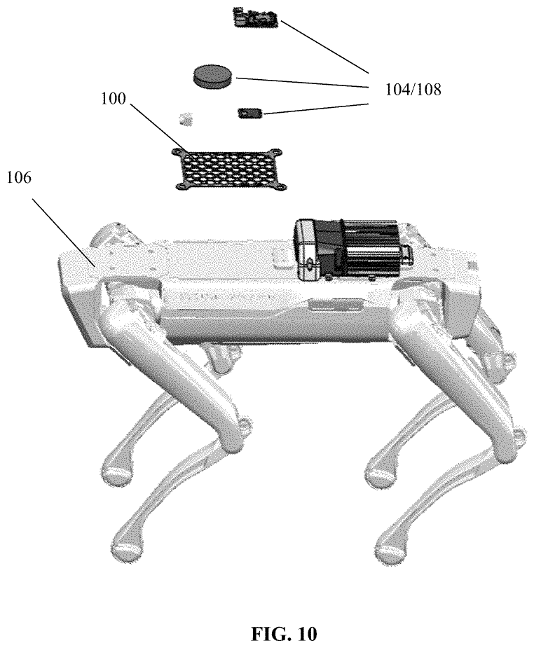

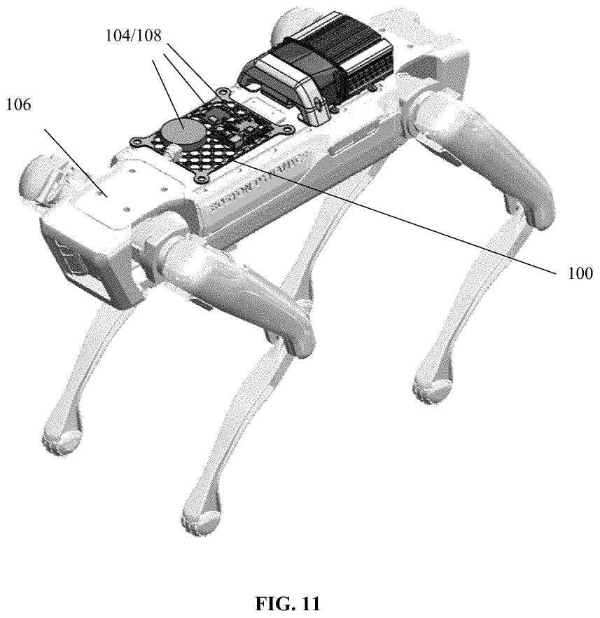

Referring to FIGS. 1 and 9-11, embodiments relate to a system 110 and method for determining a payload platform configuration. A payload 102, as used herein, includes at least one peripheral 104 to be attached to an unmanned vehicle 106. A peripheral 104 can be an operating module 108 (e.g., an integrated circuit, a processor, a software processing module, a transceiver, a sensor, a camera, etc.) for the vehicle 106. A peripheral 104 can also be an accessory 900 (see FIG. 9) (e.g., a track, a wheel, a cleat, armor plating, insulation, a weapon, a weapon system, C5ISR (Command, Control, Computers, Communications, Cyber, Intelligence, Surveillance and Reconnaissance), etc.) for the vehicle 106. The collection of peripherals 104 can be considered the payload 102 for the vehicle 106. For instance, the vehicle 106 can be an unmanned robotic unit used to perform a desired task (e.g., conduct reconnaissance for police or military tactical operation, conduct surveillance in hazardous environments, collect samples within environments that would be impossible for a human to enter, etc.). The vehicle 106 can be autonomous, semi-autonomous, or remote controlled. Attached to the vehicle 106 are operating modules 108 and/or accessories 900 to allow the vehicle to perform its intended function.

Typically, the vehicle 106 is designed by a manufacturer. The manufacturer designs the vehicle 106 and its peripherals 104 (including the placement of the peripherals 104 on the vehicle 106) with specific operational performance constraints that would satisfy the intended use of the vehicle 106 and the peripherals 104. Yet, once in the field, it may be desirable to modify the peripherals 104 to enhance the vehicle's 106 operational performance, use the vehicle 106 outside the scope of its intended use, or add other types of payloads 102, etc. However, this is difficult to do, and in some cases impossible to do, when the intended use, operational performance constraints, and peripherals 104 are pre-determined. Thus, with known systems, there is no feasible way to change the payload 102 configuration on the fly, e.g., there is no practical means to take a pre-designed vehicle 106 and modify its payload 102 (size, weight, power, number of, placement, etc.) of the peripherals 104 once the details of the operating environment where the vehicle 106 is to be used are obtained. Further, with known systems, there is no means to perform a cost-benefit analysis of making such modifications. However, embodiments of the method and system 110 disclosed herein provide such a means.

Embodiments of the method and system 110 include use of a platform 100 designed to accommodate securement of peripherals 104 to the vehicle 106. The design of the platform 100 and the location of the peripherals 104 can be determined using techniques disclosed herein. The platform 100, after being designed and fabricated, can be attached to the vehicle 106 using fasteners, mechanical locking mechanisms, magnetic locking mechanisms, adhesive, etc. The results of the method can provide a single platform 100 for the entire payload 102, or multiple platforms 100 for the single payload 102, a single platform 100 for multiple payloads 102, a plurality of payloads 102 each having a single platform 100, etc. There can be a platform 100 dedicated for an operating module(s) 108, a platform 100 dedicated for an accessory(ies) 900, or a combination of both. Some platform 100 designs can be configured to stack on top of each other. For example, there can be a first platform 100 attached to the vehicle 106, a second platform 100 attached to the first platform 100. The first platform 100 may be configured to support computer processing operating modules 108 and the second platform 100 may be configured to support sensor and camera operating modules 108. As another example, the first platform 100 can be configured to support computer processing operating modules 108 and the second platform 100 can be configured to support armor or fireproofing material accessories 900.

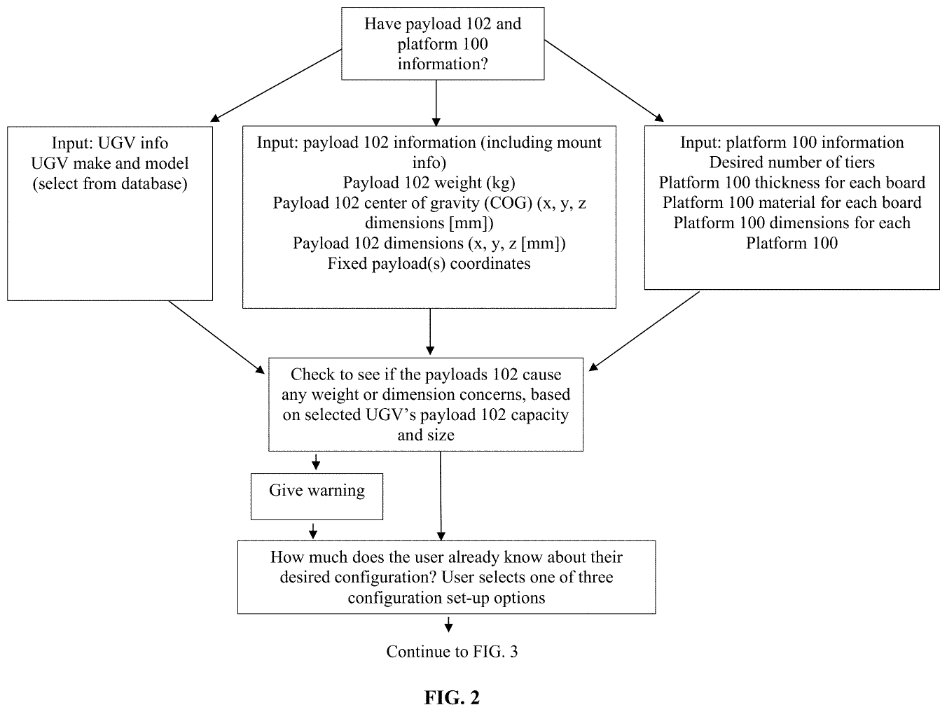

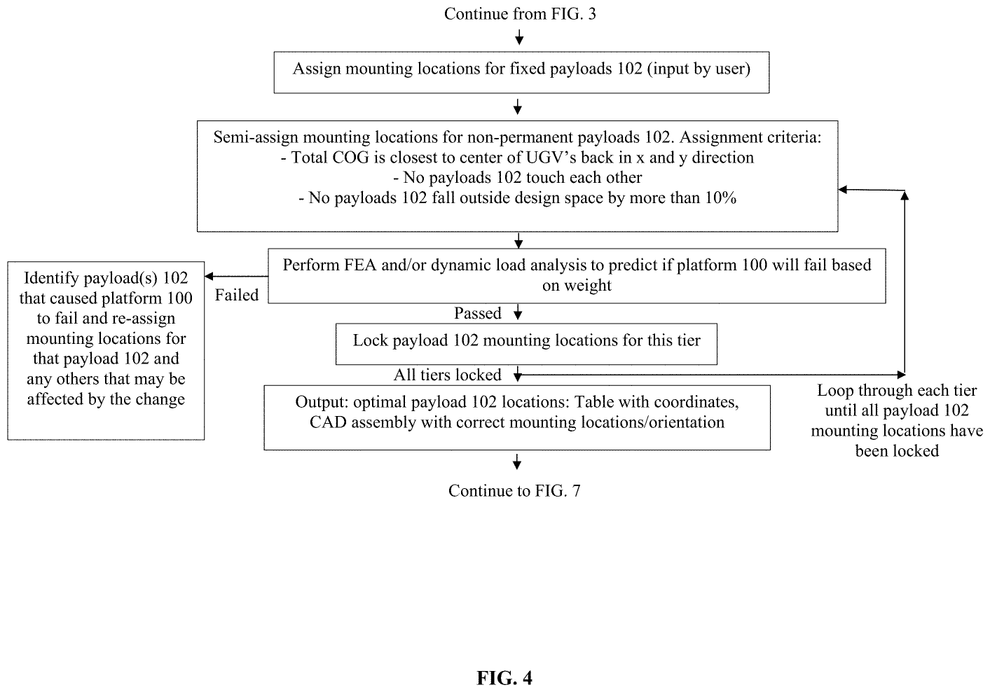

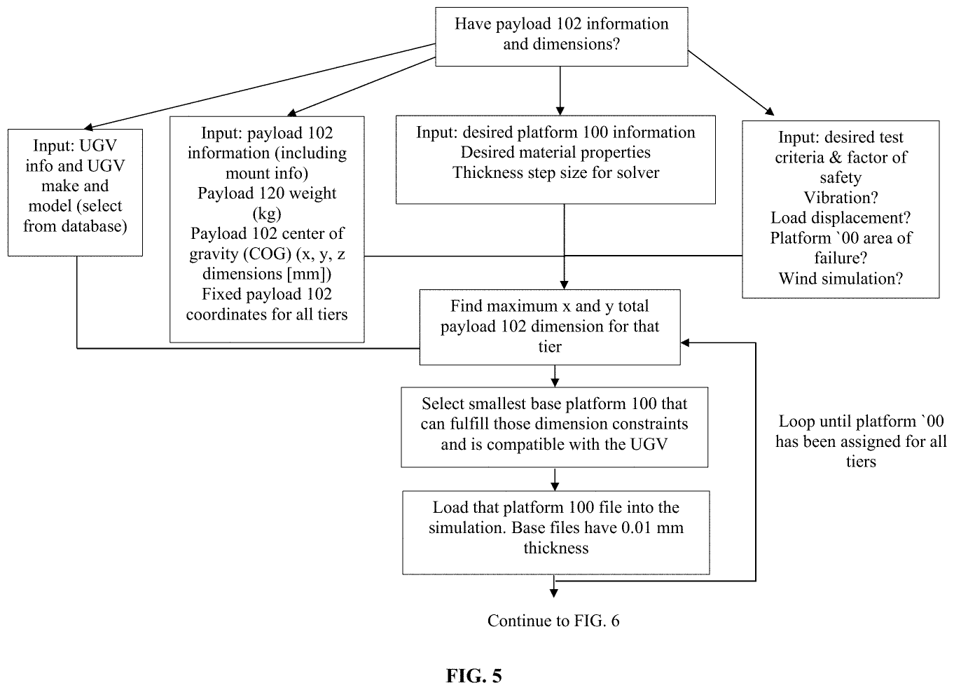

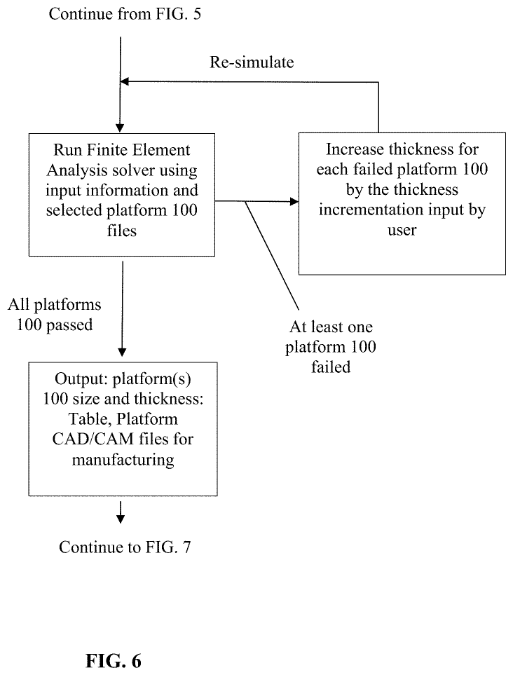

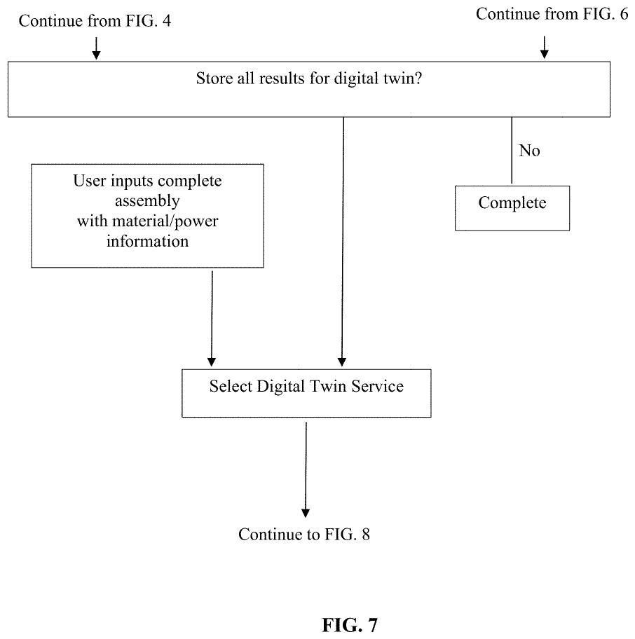

Referring to FIGS. 2-8, embodiments of the method can involve receiving platform 100 specifications. The platform 100 specifications can include which type of material to use (e.g., material properties) for the platform 100, dimensions (e.g., length, width, height) of the platform 100, weight of the platform 100, profile (e.g., square, triangular, flat, stepped, tapered, etc.) of the platform 100, the type of securement means (e.g., fasteners, adhesive, welding, soldering, etc.) to secure payloads 102 thereto or to secure the platform 100 to the vehicle 106, center of gravity for the platform 100, etc. A user can define any one or combination of these specifications, or a range thereof, as desired specifications or parameters for determining a suitable platform 100 specification. The method can use these platform 100 specifications as a guide when performing the analysis disclosed herein.

The method can involve receiving payload 102 specifications for a first payload 102. The method can involve receiving payload 102 specifications or a second payload 102. The first payload 102 can be the payload 102 designed by or recommended by the manufacturer. As noted herein, the first payload 102 is pre-determined based on a pre-determined intended-use for the vehicle 106. The second payload 102 is a desired payload 102 for the desired use of the vehicle 106. It is contemplated that second payload 102 can be different from the first payload 102. For instance, the second payload 102 may include an additional camera, a sensor that differs from the sensor used in the first payload 102, etc. However, the second payload 102 can be the same as the first payload 102. For instance, a user may wish to know whether the user-defined platform 100 can support the first payload 102, how use of the platform 100 changes the performance of the vehicle 106 if the first payload 102 is used, how the performance of the vehicle 106 can be tested when the first payload 102 is used, etc. The payload 102 specifications can include which type of peripheral 104 to use, the number of peripherals 104, the dimensions (e.g., length, width, height) for each peripheral 102, weight of each peripheral 104, the profile (e.g., square, triangular, flat, stepped, tapered, etc.) of each peripheral 102, the type of peripheral 104 securement means (e.g., fasteners, adhesive, welding, soldering, etc.), center of gravity for each peripheral 102, etc. A user can define any one or combination of these specifications, or a range thereof, as desired specifications or parameters for determining a suitable platform 100 specification. The method can use these payload 102 specifications as a guide when performing the analysis disclosed herein.

The method can involve receiving operational constraints for the vehicle 106 to which the platform 100 and the second payload 102 will be attached. The operational constraints can be based on payload specifications for the first payload 102. Presumably, the operational constraints for the vehicle 106 using the first payload 102 have been well-vetted and proven to work, and thus provides the system 110 (the system 110 carrying out the method) with a baseline from which to work. These operational constraints can be used as a guide when performing the analysis disclosed herein.

The method can use finite element analysis (FEA) and/or dynamic load analysis to generate predictions about operational performance of the vehicle 106 and corresponding properties of the platform 100. The operational performance can include factors that influence the functioning of the vehicle 106, a platform 100 of the vehicle 106, a payload 102 of the vehicle, or a peripheral 104 of the vehicle 106. These factors can include the environment within which the vehicle 106 is intended to operate, physical or chemical conditions to which the vehicle 106 is subjected, etc. Corresponding properties can include the weight-bearing and rigidity of materials, size of platform 100, shape of platform 100, and resistance to environmental factors, etc. The predictions can be based on payload 102 specifications for the second payload 102. For instance, the FEA and/or dynamic load analysis can be used to predict whether the vehicle 106 can operate within the operational constraints received regarding the first payload 102. In addition, the FEA and/or dynamic load analysis can be used to determine whether the vehicle 106, while performing outside of any one or combination of operational constraints, can still function properly for its desired purpose and without failure. The FEA and/or dynamic load analysis can be used to set the parameters for platform 100 specifications, which can include selection and placement of peripherals for the second payload 102. These parameters can be compared to the platform 100 specifications received to determine if there is a deviation. If there are one or more deviations, the system 110 can identify them for a user via the user interface. Alternatively, the system 110 can inform the user that a platform 100 with the desired specifications is not feasible for the desired second payload 102, or that the desired second payload 102 is not feasible with the platform 100. The system 110 can also provide a user with details as to which parameters (operational constraints, operational performance of the vehicle 106, etc.) are within or deviate from the required specifications. The user can then modify the parameters and system 110 can rerun the analysis, and the user can view the results.

The FEA and/or dynamic load analysis can also be used to predict an operational lifetime based upon effects of adding peripherals 104 to the vehicle's 106 power infrastructure operational environment. The FEA and/or dynamic load analysis can also factor in mechanical designs for stacking of platforms 100.

It is contemplated for the method to generate a platform 100 configuration that meets a predetermined operational performance of the vehicle 106. The predetermined operational performance can be the same as or different from the operational performance that corresponded to the first payload 102. For instance, a user can have the system 110 design a platform 100 configuration that strictly meets the operational performance set by the manufacturer based on the first payload 102 and the intended-use of the vehicle 106. Alternatively, a user can have the system 110 design a platform 100 configuration that meets a user-defined operational performance for the vehicle 106 and the intended use of the vehicle 106. In either case, the platform configuration is based on payload 102 specifications for the second payload 102 as part of the payload 102 for the intended use.

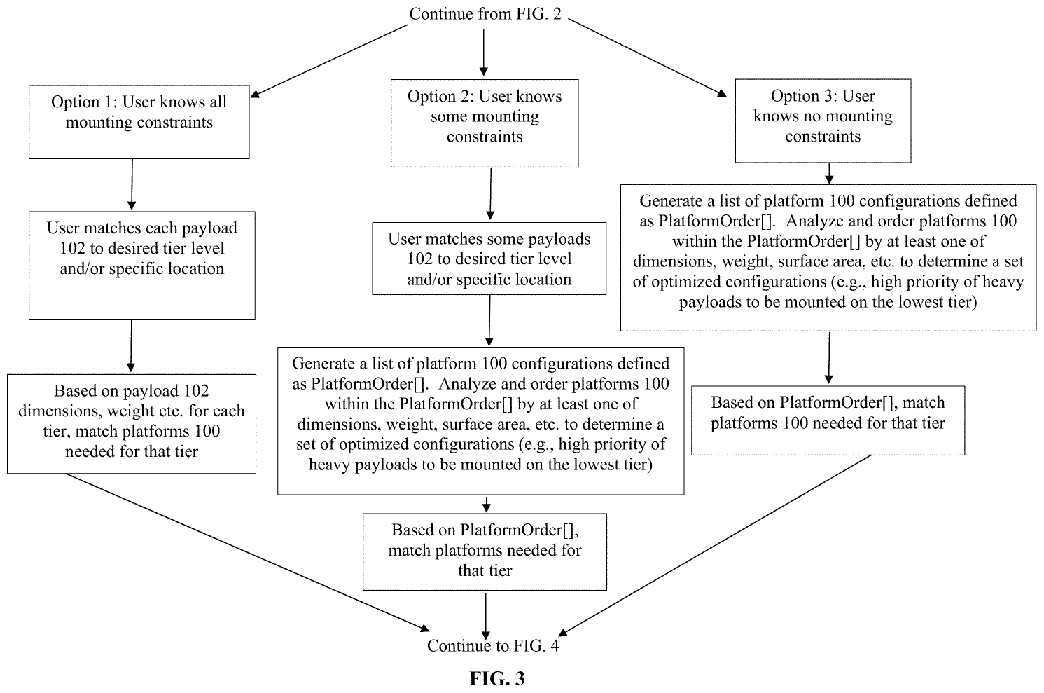

As noted herein, some embodiments can include use of more than one platform 100. The platforms 100 can be juxtaposed to each other when mounted to any location (e.g., top, bottom, side, front, rear) of the vehicle 106 and/or stacked on top (or side-by-side based on orientation or desired structural alignment) of each other. The method can involve generating a list of platform 100 configurations (for purposes of this disclosure, the list is called PlatformOrder[] (see FIG. 3). The method can involve analyzing and ordering platforms 100 within the PlatformOrder[] by dimensions, weight, surface area, etc. to determine a set of optimized configurations (e.g., high priority of heavy payloads to be mounted on the lowest tier). Thus, PlatformOrder[] can be a ranked list of all platforms 100 which are ordered by one or more of their dimensions, weight, surface area, etc. The ranked PlatformOrder[] can be used to determine the ideal configuration for where to place each platform 100 to optimize space allocation. For example, it may be beneficial to have platforms 100 that are heaviest stacked closest to the center of gravity of the vehicle 106. Ranked platform 100 dimensions can be used to determine how many of the platforms 100 can be stacked and/or placed next to each other.

With a stacked configuration, there will be at least two tiers of platforms 100. The FEA and/or dynamic load analysis can be done to determine the configuration and placement of the first tier. The FEA and/or dynamic load analysis can then use the vehicle 106 and the first tier as a combined unit to determine the configuration and placement of the second tier. The result of the second round of FEA and/or dynamic load analysis can be done by fixing the first tier in place (to not be moved or reconfigured) or be done to generate an optimal configuration and/or placement for any one or combination of the first tier or second tier. This can be applied for third, fourth, fifth, etc. tiers. It should be noted that any tier can have any number of platforms 100 and/or payloads 102.

In addition, or in the alternative to generating a platform 100 configuration that meets a predetermined operational performance of the vehicle 106, the method can provide a user with an operational performance result for a predetermined platform 100 configuration. The predetermined platform 100 configuration is the platform 100 configuration based on the platform 100 specifications received in a preliminary step discussed above. The operational performance result is a predicted operational performance of the vehicle 106 determined via FEA and/or dynamic load analysis and is based on payload 102 specifications for the second payload 102. As noted herein, the FEA and/or dynamic load analysis can also be used to predict operational lifetime based upon effects of adding peripherals 104 to the vehicle's 106 power infrastructure operational environment. Thus, the operational performance result can include operational lifetime as a factor.

Once a user is satisfied with the results, the FEA and/or dynamic load analysis can be used to fabricate a platform 100 as needed. This can involve developing a build file for a desired manufacturing apparatus, wherein the FEA and/or dynamic load analysis is used to set the parameters of the build file. These parameters can control product characteristics for the platform 100 by generating operational parameters to control the manufacturing apparatus and predictively optimize them to meet design requirements. FEA and/or dynamic load analysis can also be used to take into account desired material and mechanical characteristics and other parameters that enable the platform 100 to be made via the desired manufacturing process. For example, material properties, mechanical properties, minimization of material, structural integrity, reduction of weight, transfer of moments and force vectors, etc. can be mathematically modeled and represented by variables during the FEA and/or dynamic load analysis. Algorithmic functions including use of these variables can then be generated and incorporated into the build file. The build file can then be operated on by a processor of the manufacturing apparatus to fabricate the platform 100.

For example, a user can input at least one variable into the manufacturing apparatus, such as the dimensions and desired weight of the platform 100 to be produced. The processor of the manufacturing apparatus can then run at least one algorithm embedded in the build file to generate at least one operating parameter that would generate a platform 100 exhibiting the desired characteristics. In some embodiments, the manufacturing apparatus can be programmed (via the build file) to generate a plurality of operating parameters as a function of another operating parameter. For example, the manufacturing apparatus may generate a set of operating parameters for each material available to a user that would result in a platform 100 meeting applicable specifications such as dimensions, shape, weight, etc. that would provide the desired mechanical properties. A user may then select the material with the most desirable characteristics to be used by the manufacturing apparatus to make the platform 100.

In some embodiments, FEA and/or dynamic load analysis can be used to optimize topology of the platform 100 and/or the payload 102. While it is contemplated for a user to input initial specifications or parameters related to topology (e.g., dimensions, placement, shape, size, number of units, etc.) for the platform 100 and the payload 102, FEA and/or dynamic load analysis can be used to optimize the topology for desired design criteria. A new or updated build file, such as an stl file, can then be generated.

FEA generally involves defining a domain for a problem and dividing the domain into a collection of subdomains. Each subdomain can be mathematically represented by at least one set of element equations. The FEA can then involve recombining all sets of element equations into a global set of equations that can be solved. The FEA can involve use of numerical methods. For instance, the FEA can involve a numerical finite element method technique.

As noted herein, the vehicle 106 can be a robotic unit. It is contemplated for the robotic unit to be an unmanned ground vehicle, which can include a wheeled vehicle, a tracked vehicle, a walking vehicle, etc. An exemplary embodiment shows the vehicle 106 being a quadrupedal robot. Other types of vehicles 106 can be used, which can include manned or unmanned vehicles, aerial vehicles, water vehicles, space vehicles, etc.

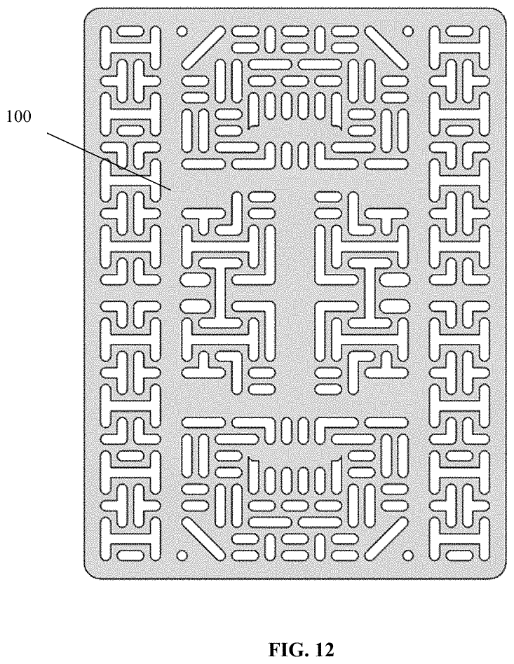

The platform 100 can be designed as a mounting plate that accepts modular configurations. As a non-limiting example, the platform 100 can be designed as a pegboard or include a pegboard. The pegboard can be configured to attach to the vehicle 106 (e.g., using fasteners, mechanical locking mechanisms, magnetic locking mechanisms, adhesive, etc.). The pegboard can be a member having at least one aperture 112 (a through-hole, dead-hole, slot, channel, etc.) configured to receive a connector (e.g., peg, pin, bolt, screw, etc.). FIG. 1 shows an exemplary through-hole design. FIG. 12 shows an exemplary slot design. The connector can be part of or attached to a peripheral 104, and can be inserted into aperture 112 to facilitate connection of the peripheral 104 to the pegboard. The mechanical engagement between the connector and the aperture 112 can be an interference fit but it need not be. In addition to the connector-aperture 112 fit, other means for connecting the peripheral 104 to the pegboard can be used (e.g., using fasteners, mechanical locking mechanisms, magnetic locking mechanisms, adhesive, etc.).

As noted herein, the payload 102 can include an operating module 108 configured to attach to the pegboard. The operating module 108 can be a peripheral 104 that provides a function to the vehicle 106 or allows command and control of at least an aspect of the vehicle 106. For instance, the operating module 108 can be a camera or a sensor to allow the vehicle 106 to perform desired surveillance. As another example, the operating module 108 can be a processor configured to facilitate command and control of a peripheral 104 or the vehicle 106 itself. For instance, the control module 108, when connected to the platform 100, can be placed into communication (hardwire or wireless) with a peripheral 104 or motors and actuators of the vehicle 106. A hardwire connection can be via interconnects formed on the control module 108, the peripheral 104, the motors and actuators of the vehicle 106, etc. that connect with each other. The hardwire connection can be electrical and/or optical. The wireless connection can be via transceivers. It is contemplated for the vehicle 106 to have an electrical power supply (e.g. a battery), and further contemplated for the control modules 108 to receive electrical power therefrom.

In some embodiments, the vehicle 106, and any one or combination of the peripherals 104, can be controlled by a remote computer device. For instance, the computer device can be in communication with the vehicle 106, or any of its peripherals 104, via a wireless connection to facilitate data transmissions between the computer device and the vehicle 106 and/or the peripheral(s) 104. In addition, any of the components of the vehicle 106 or any of the peripherals 104 can have an application programming interface (API) and/or other interface configured to facilitate the computer device that is in communication with the vehicle 106 executing commands and controlling aspects of the vehicle 106. Embodiments of the computer device can be programmed to generate a user interface configured to facilitate control and display of various operational aspects of the vehicle 106.

There can be any number or combination of peripherals 104 and operating modules 108 for a vehicle 106. The peripheral 104 itself can include any number or combination of operating modules 108. In some embodiments, each of the first payload 102 and the second payload 102 can include an operating module 108 that is a peripheral 104 device for the vehicle 106. In some embodiments, each of the first payload 102 and the second payload 102 can include one or more of operating modules 108 including at least one peripheral 104 device for the vehicle 106. Each of the first payload 102 and the second payload 102 can include one or more of payloads 102, which may or may not be unrelated to the operation of the vehicle 106 except to be transported by the vehicle 106.

As noted herein, a peripheral 104 can be an accessory 900 (e.g., a track, a wheel, a cleat, armor plating, insulation, a weapon, a weapon system, etc.) for the vehicle 106. In some embodiments, the platform 100 itself can be configured as an accessory 900 for the vehicle 106. Thus, the method can be used to design and fabricate a platform 100 that will be used as an accessory 900 for the vehicle 106.

Some embodiments relate to a system 110 for determining a payload 102 platform 100 configuration. The system 110 can include a processor 114 having instructions stored thereon, which when executed will cause the processor 114 to execute any of the method steps disclosed herein. For instance, the processor 114 can be configured as, or programmed to include, a platform 100/payload 102 analytic module.

Any of the processors disclosed herein can be an integrated circuit or other electronic device (or collection of devices) capable of performing an operation on at least one instruction including, without limitation, a reduced instruction set core (RISC) processor, a complex instruction set (CISC) processor, a microcontroller unit (MCU) processor, a central processing unit (CPU) processor, a graphical processing unit (GPU), a digital signal processor (DSP), etc. The processor can be hardware, software, or a combination of both. The processor can be scalable, parallelizable, optimized for multi-thread processing capabilities, etc. Various functional aspects of the processor may be implemented solely as software or firmware associated with the processor.

Any of the processors disclosed herein can be optionally associated with a memory. Embodiments of the memory can include a volatile memory store (such as RAM), non-volatile memory store (such as ROM, flash memory, etc.) or some combination of the two. For instance, the memory can include, but is not limited to, RAM, ROM, EEPROM, flash memory or other memory technology CDROM, DVD, or other optical storage, magnetic cassettes, magnetic tape, magnetic disk storage or other magnetic storage devices, or any other medium which can be used to store the desired information and which can be accessed by the processor. According to exemplary embodiments, the memory can be a non-transitory computer-readable medium. The term “computer-readable medium” (or “machine-readable medium”) as used herein is an extensible term that refers to any medium or any memory, that participates in providing instructions to the processor for execution, or any mechanism for storing or transmitting information in a form readable by a machine (e.g., a computer). Such a medium may store computer-executable instructions to be executed by a processing element and/or control logic, and data that is manipulated by a processing element and/or control logic, and may take many forms, including but not limited to, non-volatile medium, volatile medium, and transmission media.

Transmission media includes coaxial cables, copper wire and fiber optics, including the wires that include or form a bus. Transmission media can also take the form of acoustic or light waves, such as those generated during radio-wave and infrared data communications, or other form of propagated signals (e.g., carrier waves, digital signals, etc.). Forms of computer-readable media include, for example, a floppy disk, a flexible disk, hard disk, magnetic tape, or any other magnetic medium, a CD-ROM, any other optical medium, punch-cards, paper-tape, any other physical medium with patterns of holes, a RAM, a PROM, and EPROM, a FLASH-EPROM, any other memory chip or cartridge, a carrier wave as described hereinafter, or any other medium from which a computer can read.

Instructions for implementation of any of the methods disclosed herein can be stored on the memory in the form of computer program code. The computer program code can include program logic, control logic, or other algorithms that may or may not be based on artificial intelligence (e.g., machine learning techniques, artificial neural network techniques, etc.).

The processor 114 of the system 110 can include or be part of a computer device. The system 110, via the computer device, can provide a user interface to allow a user to interact with the system 110, provide inputs to the system 110, view outputs by the system 110, control aspects of the system 110, etc. The user interface can be displayed via a display of the processor 114 and be configured to receive a modification for the platform 100 specifications, the payload 102 specifications, and/or the operational constraints. The processor 114 can be configured to dynamically generate the platform 100 configuration that meets a predetermined operational performance of the vehicle 106 and/or the operational performance result for a predetermined platform 100 configuration based on the modification. For instance, a user can input desired platform 100 specifications, payload 102 specifications, and/or operational constraints via the user interface, wherein the processor 114, via the FEA and/or dynamic load analysis, can automatically and in real time generate the platform 100 configuration that meets a predetermined operational performance of the vehicle 106 and/or the operational performance result for a predetermined platform 100 configuration based on the modification. The specifications and/or rendered 3-dimensional drawings for the platform 100 having the generated specifications suitable for the parameters can be displayed via the user interface. If a user enters modifications, the processor 114 can cause the user interface to update the generated specifications and drawings of the platform 100 for display. Once a user is satisfied, the processor 114 can generate a build file to be used by a desired manufacturing apparatus or process, as described herein. The processor 114 can generate the build file to be stored in memory and transferred to the processor of the manufacturing apparatus. In some embodiments, the processor 114 is in communication with the processor of the manufacturing apparatus via a communication interface, thereby facilitating automatic and real time transfer of the build file. A system can also be configured to operate autonomously without a user manually participating in some or all of the design and review steps.

Some embodiments relate to a method for determining payload 102 placement on a platform 100. For instance, the method can involve receiving platform 100 specifications. The method can involve receiving payload 102 specifications for a first payload 102 and a second payload 102. The method can involve receiving operational constraints for a vehicle 106 to which the platform 100 and the second payload 102 will be attached. The operational constraints can be based on payload 102 specifications for the first payload 102. The method can involve using FEA and/or dynamic load analysis to generate predictions about operational performance of the vehicle 106 and corresponding properties of the platform 100. The predictions can be based on payload 102 specifications for the second payload 102. The method can involve generating a payload 102 placement arrangement for the second payload 102 that meets a predetermined operational performance of the vehicle 106 (e.g., generate a payload 102 placement arrangement for the second payload 102 that meets a user-defined operational performance for the vehicle 106). In addition, or in the alternative, the method can involve generating an operational performance result for a predetermined payload 102 placement arrangement for the second payload 102 (e.g., generate an operational performance result for the vehicle 106 based on a user-defined payload 102 placement arrangement using the second payload 102). The user-defined payload 102 placement arrangement can include the size, weight, power, number of, placement, etc. of peripherals 104 for any one or combination of platforms 100 to be used with the vehicle 106.

The method can involve performing the analyses for any number of second payloads 102. For instance, the method can involve performing the analysis for a desired second payload 102 and performing the analysis for another desired second payload 102. A user, or the system 110, can compare results of the two second payloads 102 and determine which second payload 102 is optimal for the intended use of the vehicle 106. As another example, the method can involve performing the analysis for a desired second payload 102. The result can be used to generate a platform 100 and/or payload 102 configuration for an intended use of the vehicle 106. The intended use may change or the operational environment may change for the vehicle 106. The method can then involve performing the analysis again. The result can be used to modify the second payload 102 or generate a new second payload 102 for the new operational environment.

In some embodiments, the FEA and/or dynamic load analysis can involve a numerical finite element method technique.

In some embodiments, the vehicle 106 can be a robotic unit.

In some embodiments, the vehicle 106 can be an unmanned ground vehicle.

In some embodiments, the vehicle 106 can be a quadrupedal robot.

In some embodiments, the platform 100 can include a pegboard configured to attach to the vehicle 106. The payload 102 can include an operating module 108 configured to attach to the pegboard.

In some embodiments, each of the first payload 102 and the second payload 102 can include an operating module 108 that is a peripheral 104 device for the vehicle 106.

In some embodiments, each of the first payload 102 and the second payload 102 can include one or more of operating modules 108 including at least one peripheral 104 device for the vehicle 106. Each of the first payload 102 and the second payload 102 can include one or more of payloads 102, which may or may not unrelated to the operation of the vehicle 106 except to be transported by the vehicle 106.

In some embodiments, the platform 100 can be configured as an accessory 900 for the vehicle 106.

Some embodiments can relate to a system for determining payload 102 placement on a platform 100. The system can include a processor having instructions stored thereon which when executed will cause the processor 114 to execute any of the method steps disclosed herein. For instance, the processor 114 can be configured as, or programmed to include, a platform 100/payload 102 analytic module. The system 110 can include a user interface configured to receive a modification for the platform 100 specifications, the payload 102 specifications, and/or the operational constraints. The processor 114 can be configured to dynamically generate the platform 100 placement arrangement that meets a predetermined operational performance of the vehicle 106 and/or the operational performance result for a predetermined platform 100 placement arrangement based on the modification.

As can be appreciated from this disclosure, the methods and systems 110 described herein provide the ability to derive a platform 100 and/or payload 102 configuration for a desired payload (e.g., the second payload 102) for the vehicle 106 that deviates from the Manufacturer's suggested payload (e.g., the first payload 102) configuration. The methods and systems 110 can receive operational constraints for the vehicle 106 based on using the first payload 102 and then use those as a guide to generate a platform 100/payload 102 configuration to allow a user to use the desired second payload 102. The methods and systems 110 also allow a user to define or review operational constraints and/or operational performances for the vehicle 106. Thus, a user can define an expected use case for the vehicle 106 using the second payload 102. The expected use case can include using the vehicle 106 in a certain environment (e.g., high or low temperature, high radiation, high signal noise, high light pollution, under water, etc.). These environmental factors can be defined as mathematical parameters for the operational constrains and/or operational performances.

As noted herein, the methods and system 110 disclosed herein can also allow a user to engage in cost-benefit analyses regarding size, weight, power, etc. of the peripherals 104 used for the payload 102. The system 110 can do this automatically via use of cost functions, for example. A user can also manually engage in such cost-benefit analyses by manually entering modifications to the specifications and reviewing the results.

Some embodiments can relate to a method for manufacturing a payload platform. The method can involve receiving platform 100 specifications. The method can involve receiving payload 102 specifications for a first payload 102 and a second payload 102. The method can involve receiving operational constraints for a vehicle 106 to which the platform 100 and the second payload 102 will be attached. The operational constraints can be based on payload 102 specifications for the first payload 102. The method can involve using FEA and/or dynamic load analysis to generate predictions about operational performance of the vehicle 106 and corresponding properties of the platform 100. The predictions can be based on payload 102 specifications for the second payload 102. The method can involve generating a platform 100 configuration that meets a predetermined operational performance of the vehicle 106. The platform 100 configuration can be based on payload 102 specifications for the second payload 102. In addition, or in the alternative, the method can involve generating an operational performance result for a predetermined platform 100 configuration. The operational performance result can be based on payload 102 specifications for the second payload 102.

The method can involve fabricating the platform 100. This can be achieved by creating a build file, as discussed herein, to be used with a manufacturing apparatus or process. Fabricating the platform 100 can involve any one or combination of: an additive manufacturing technique, a laser cutting technique, a mold manufacturing technique, subtractive manufacturing (e.g., waterjet, cnc machine, etc.), etc.

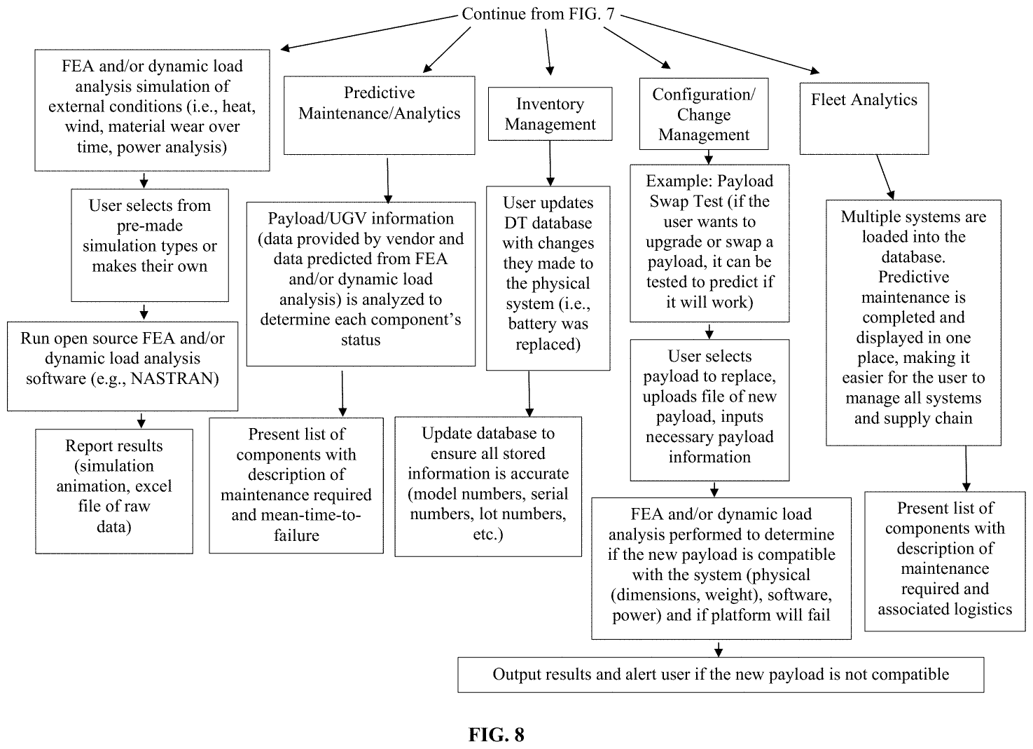

As noted herein, the disclosed systems 110 and methods are used to generate predictions about operational performances and/or operational lifetimes for the vehicle 106, the platform 100, and/or the payload 102. Such predictions can also be used to provide fleet analytics or fleet management. (See FIG. 8). For instance, the system 110, having a compilation of the predictions of multiple vehicles 106 with designed platforms 100 and designed payloads 102, can manage maintenance of the fleet of vehicles 106. The predictions can be used to determine when maintenance should be performed on the vehicles 106, platforms 100, and/or payloads 102 for any one or combination of the vehicles 106 in the fleet. Maintenance schedules based on predictive maintenance can be generated for preventative maintenance measures.

As noted herein, known vehicle systems are limited to using native payload support systems that are designed to only operate with OEM components, placement, and configurations. For example, known systems design the vehicle 106 and vehicle constraints and for a single payload 102 configuration and for a very specific and limited use. With known systems, there is no way to re-evaluate the payload 102 configuration for customization. For instance, an OEM will provide a vehicle 106 with a mount that only allows a user to mount a specific type of payload 102 (e.g., a camera, an actuator arm, etc.) to that specific mount and nowhere else on the vehicle 106. In most cases, the mount is specific to the specific type of payload 102, and thus a user cannot move payload-1 from mount-1 to mount-2. Embodiments disclosed herein, however, do provide such means for rearrangement and customization of payloads 102.

First, the methods and systems 110 described herein facilitate generating a platform 100 “on-the-fly” that allows a user to design one or more payloads 102 that meet one or more specific purposes for the vehicle 106. Second, the platform 100 facilitates customization of the payload(s) 102. Third, the platform 100 is designed to ensure optimal operational performance of the vehicle 106. Fourth, the method allows a user to optimize the number and placement of the platform(s) 100 and customized payload(s) 102.

Thus, while some embodiments discuss use of a first payload 102 for designing a platform 100 for a second payload 102 or designing a second payload 102 configuration, this need not be the case. In some embodiments, the methods and systems 110 disclosed can be used to design a platform 100 and/or a payload 102 configuration merely based on the vehicle 106 constraints. For instance, a method for determining a payload platform configuration can involve receiving platform 100 specifications. The method can further involve receiving operational constraints for a vehicle 106 to which the platform 100 and a payload 102 will be attached. The method can involve receiving payload 102 specifications for a payload 102, the payload 102 being a customized payload 102 for the vehicle 106. The method can involve using finite element analysis (FEA) and/or dynamic load analysis to generate predictions about operational performance of the vehicle 106 and corresponding properties of the platform 100, the predictions being based on payload specifications for the payload 102. The method can involve generating at least one of: a platform 100 configuration that meets a predetermined operational performance of the vehicle 106, the platform 100 configuration being based on payload 102 specifications for the payload 102; or an operational performance result for a predetermined platform 100 configuration, the operational performance result being based on payload 102 specifications for the payload 102.

One of the key aspects of the inventive concept is the platform 100 design. The inventive platform 100 design provides many of the technical advantages discussed herein. In an exemplary embodiment, a payload platform for an unmanned vehicle 106 can include a mounting plate configured to accept at least one modular payload 102 via an aperture 112 arrangement formed within the mounting plate. With the connector being apart attached to a peripheral 104 and insertable into an aperture 112 of the aperture 112 arrangement, the aperture 112 arrangement can be configured to facilitate repositioning of at least one modular payload 102. For instance, a user can attach a payload 102 at a specific location on the platform 100 and reposition it as desired. It is contemplated for the repositioning to be preceded by the FEA and/or dynamic load analysis discussed herein to determine the operational performance of the vehicle 106, but it need not be.

It will be understood that modifications to the embodiments disclosed herein can be made to meet a particular set of design criteria. For instance, any of vehicles 106, platforms 100, operating modules 108, peripherals 104, accessories 900, or any other component can be any suitable number or type of each to meet a particular objective. Therefore, while certain exemplary embodiments of the platform 100 and methods of making and using the same disclosed herein have been discussed and illustrated, it is to be distinctly understood that the invention is not limited thereto but can be otherwise variously embodied and practiced within the scope of the following claims.

It will be appreciated that some components, features, and/or configurations can be described in connection with only one particular embodiment, but these same components, features, and/or configurations can be applied or used with many other embodiments and should be considered applicable to the other embodiments, unless stated otherwise or unless such a component, feature, and/or configuration is technically impossible to use with the other embodiment. Thus, the components, features, and/or configurations of the various embodiments can be combined together in any manner and such combinations are expressly contemplated and disclosed by this statement.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein. Additionally, the disclosure of a range of values is a disclosure of every numerical value within that range, including the end points.

What is claimed is:

1. A method for determining a payload platform configuration, the method comprising:
receiving platform specifications;
receiving payload specifications for a first payload and a second payload;
receiving operational constraints for a vehicle to which the platform and the second payload will be attached, the operational constraints being based on payload specifications for the first payload;
using finite element analysis (FEA) and/or dynamic load analysis to generate predictions about operational performance of the vehicle and corresponding properties of the platform, the predictions being based on payload specifications for the second payload; and
generating at least one of:
a platform configuration that meets a predetermined operational performance of the vehicle, the platform configuration being based on payload specifications for the second payload; or
an operational performance result for a predetermined platform configuration, the operational performance result being based on payload specifications for the second payload.

2. The method recited in claim 1, wherein:
the FEA and/or dynamic load analysis involves a numerical finite element method technique.

3. The method recited in claim 1, wherein:
the vehicle is a robotic unit.

4. The method recited in claim 1, wherein:
the vehicle is an unmanned ground vehicle.

5. The method recited in claim 1, wherein:
the vehicle is a quadrupedal robot.

6. The method recited in claim 1, wherein:
the platform includes a mounting plate configured to attach to the vehicle; and
the payload includes an operating module configured to attach to the pegboard.

7. The method recited in claim 1, wherein:
each of the first payload and the second payload includes an operating module that is a peripheral device for the vehicle.

8. The method recited in claim 1, comprising:
each of the first payload and the second payload includes one or more of:
operating modules including at least one peripheral device for the vehicle; and/or
payloads unrelated to the operation of the vehicle except to be transported by the vehicle.

9. The method recited in claim 1, wherein:
the platform is configured as an accessory for the vehicle.

10. A system for determining a payload platform configuration, the system comprising:
a processor having instructions stored thereon which when executed will cause the processor to execute the method steps of claim 1;
a user interface configured to receive a modification for the platform specifications, the payload specifications, and/or the operational constraints; and
the processor is configured to dynamically generate the platform configuration that meets a predetermined operational performance of the vehicle and/or the operational performance result for a predetermined platform configuration based on the modification.

11. A method for determining payload placement on a platform, the method comprising:
receiving platform specifications;
receiving payload specifications for a first payload and a second payload;
receiving operational constraints for a vehicle to which the platform and the second payload will be attached, the operational constraints being based on payload specifications for the first payload;
using finite element analysis (FEA) and/or dynamic load analysis to generate predictions about operational performance of the vehicle and corresponding properties of the platform, the predictions being based on payload specifications for the second payload; and
generating at least one of:
a payload placement arrangement for the second payload that meets a predetermined operational performance of the vehicle; or
an operational performance result for a predetermined payload placement arrangement for the second payload.

12. The method recited in claim 11, wherein:
the FEA and/or dynamic load analysis involves a numerical finite element method technique.

13. The method recited in claim 11, wherein:
the vehicle is a robotic unit.

14. The method recited in claim 11, wherein:
the vehicle is an unmanned ground vehicle.

15. The method recited in claim 11, wherein:
the vehicle is a quadrupedal robot.

16. The method recited in claim 11, wherein:
the platform includes a pegboard configured to attach to the vehicle; and
the payload includes an operating module configured to attach to the pegboard.

17. The method recited in claim 11, wherein:
each of the first payload and the second payload includes an operating module that is a peripheral device for the vehicle.

18. The method recited in claim 11, comprising:
each of the first payload and the second payload includes one or more of:
operating modules including at least one peripheral device for the vehicle; and/or
payloads unrelated to the operation of the vehicle except to be transported by the vehicle.

19. The method recited in claim 11, wherein:
the platform is configured as an accessory for the vehicle.

20. A system for determining payload placement on a platform, the system comprising:
a processor having instructions stored thereon which when executed will cause the processor to execute the method steps of claim 11;
a user interface configured to receive a modification for the platform specifications, the payload specifications, and/or the operational constraints;
the processor is configured to dynamically generate the platform placement arrangement that meets a predetermined operational performance of the vehicle and/or the operational performance result for a predetermined platform placement arrangement based on the modification.

21. A method for manufacturing a payload platform, the method comprising:
receiving platform specifications;
receiving payload specifications for a first payload and a second payload;
receiving operational constraints for a vehicle to which the platform and the second payload will be attached, the operational constraints being based on payload specifications for the first payload;
using finite element analysis (FEA) and/or dynamic load analysis to generate predictions about operational performance of the vehicle and corresponding properties of the platform, the predictions being based on payload specifications for the second payload;
generating at least one of:
a platform configuration that meets a predetermined operational performance of the vehicle, the platform configuration being based on payload specifications for the second payload; or
an operational performance result for a predetermined platform configuration, the operational performance result being based on payload specifications for the second payload; and
fabricating the platform.

22. The method of claim 21, wherein:
fabricating the platform involves any one or combination of: an additive manufacturing technique, a laser cutting technique, a mold manufacturing technique, or subtractive manufacturing.

23. A method for determining a payload platform configuration, the method comprising:
receiving platform specifications;
receiving operational constraints for a vehicle to which the platform and a payload will be attached;
receiving payload specifications for a payload, the payload being a customized payload for the vehicle;
using finite element analysis (FEA) and/or dynamic load analysis to generate predictions about operational performance of the vehicle and corresponding properties of the platform, the predictions being based on payload specifications for the payload; and
generating at least one of:
a platform configuration that meets a predetermined operational performance of the vehicle, the platform configuration being based on payload specifications for the payload; or
an operational performance result for a predetermined platform configuration, the operational performance result being based on payload specifications for the payload.

24. A payload platform for an unmanned vehicle, the payload platform comprising:
a mounting plate configured to accept at least one modular payload via an aperture arrangement formed within the mounting plate, wherein the aperture arrangement is configured to facilitate repositioning of the at least one modular payload.
